(19) United States
(12) Patent Application Publication
(10) Pub. No.: US 2004/0153918 A1
(43) Pub. Date: Aug. 5, 2004

(54) Tamper-resistant computer program product

(75) Inventors: Hisae Tanaka, Osaka (JP); Motoshi Ito, Osaka (JP); Yoshikazu Yamamoto, Osaka (JP)

Correspondence Address: MERCHANT & GOULD PC, P.O. BOX 2903, MINNEAPOLIS, MN, 55402-0903, US

(73) Assignee: MATSUSHITA ELECTRIC INDUSTRIAL CO.,, Kadoma-shi (JP)

(21) Appl. No.: 10/408,960

(22) Filed: Apr. 8, 2003

(30) Foreign Application Priority Data
Apr. 8, 2002 (JP) 2002-104828

(51) Int. Cl. G01R 31/28

(52) U.S. Cl. 714/724

(57) ABSTRACT

A control program to be stored in a program memory of a device includes a protection program with an error correction code added thereto as a portion to be protected from tampering, and a non-protection program containing an instruction for error-correcting the protection program and an instruction for invoking a corrected program obtained as a result of the error correction. A microcomputer allows an error correction circuit to error-correct the protection program read from the program memory, and reads the corrected program from a rewritable memory for execution.

### BACKGROUND OF THE INVENTION

1. Field of the Invention

The present invention relates to a control program, a device including the control program, a method for creating the control program, and a method for executing the control program.

2. Description of the Related Art

Examples of programs and software include a control program and a contents program, such as music and video. In the following description, unless otherwise specified, a “program” and “software” refer to a control program. The control program is different from a general contents program in the following point: the control program operates a microcomputer based on its instructions (i.e., the control program controls the operation of the microcomputer), whereas the general contents program is read in accordance with an instruction from the microcomputer.

The contents program is typically digitized, and therefore, the problem associated with copyright is becoming serious. As one solution to this problem, there is encryption of the contents program. When the contents program is encrypted, it is required to decrypt a code in order to reproduce the encrypted contents program. Those who develop a reproducing apparatus for reproducing an encrypted contents program sign a license contract with a code creator, obtain a method for decrypting a code, and incorporate it into a reproducing apparatus.

In the case where a method for decrypting a code is incorporated into a hardware device, such as an LSI, only an expert having knowledge of a technique for producing an LSI can analyze an algorithm in the LSI. However, in the case where a code is decrypted by software, there is a possibility that a third party (e.g., a hacker) may disassemble an execution file of the software, thereby decrypting and tampering with the code without authorization. In order to challenge such a hacker, a software technique that makes it difficult to decrypt a code is being developed.

However, it may not be impossible that a program for performing decryption processing only with a software technique is decrypted and tampered with by a software technique. Furthermore, incorporation of a method for decryption, as hardware such as an LSI into a device tends to become disadvantageous in terms of development speed and cost in the recent developing competition.

### SUMMARY OF THE INVENTION

Therefore, with the foregoing in mind, it is an object of the present invention to provide a control program and a device capable of effectively preventing tampering by a hacker and the like at lower cost.

In order to achieve the above-mentioned object, a computer program product of the present invention includes a medium for embodying a computer program for controlling an operation of a device having a CPU via the CPU. The computer program includes: a protection program with an error correction code added thereto; and a non-protection program containing an instruction for error-correcting the protection program and an instruction for invoking a corrected program that has been subjected to the error correction.

These and other advantages of the present invention will become apparent to those skilled in the art upon reading and understanding the following detailed description with reference to the accompanying figures.

### BRIEF DESCRIPTION OF THE DRAWINGS

FIG. 1 is a block diagram showing an example of a configuration of a device in Embodiment 1 according to the present disclosure.

FIG. 2 is a flow chart illustrating a method for creating an executable format of a control program stored in a program memory in Embodiment 1 according to the present disclosure.

FIG. 3 shows a configuration of an inner code (PI) of a DVD according to the present disclosure.

FIG. 4 is a flow chart illustrating an example of a method for error-correcting a protection program in Embodiment 1 according to the present disclosure.

FIG. 5 is a flow chart illustrating a method for executing an instruction of the protection program in Embodiment 1 according to the present disclosure.

FIG. 6 is an arrangement diagram of a program region in program copying processing in Embodiment 1 according to the present disclosure.

FIG. 7 is an arrangement diagram of a program region in program correction processing in Embodiment 1 according to the present disclosure.

FIG. 8 is an arrangement diagram of a program region in module invoking processing in Embodiment 1 according to the present disclosure.

FIG. 9 shows a configuration of a corrected program after being error-corrected by an error correction circuit in Embodiment 1 according to the present disclosure.

FIG. 10 shows an address space with respect to a microcomputer in Embodiment 1 according to the present disclosure.

FIG. 11 is a flow chart illustrating a method for creating an executable format of a control program stored in a program memory in Embodiment 2 according to the present disclosure.

FIG. 12 is a flow chart illustrating a method for converting binary data in Embodiment 2 according to the present disclosure.

FIG. 13 is a circuit diagram showing a configuration of a scramble circuit used for data conversion in Embodiment 2 according to the present disclosure.

FIG. 14 is a block diagram showing an example of a configuration of a device in Embodiment 2 according to the present disclosure.

FIG. 15 is a flow chart illustrating a method for executing an instruction of the control program in Embodiment 2 according to the present disclosure.

### DESCRIPTION OF THE PREFERRED EMBODIMENTS

An error correction code is added to a portion to be protected from tampering in a computer program (protection program), and error correction is performed using the error correction code when the protection program is executed. Because of this, as long as tampering is in a correctable range even if the protection program is tampered with, the tampered protection program can be returned to the state before tampering. This enables a computer program product to be provided, which is capable of effectively preventing tampering of a program by a hacker and the like.

It is preferable that the above-mentioned computer program controls a device including an error correction circuit, and the instruction for error-correcting the protection program allows the error correction circuit to perform the error correction.

Thus, error correction is performed by a hardware circuit of the device, whereby an operation of a program cannot be analyzed even by disassembling the program. This can prevent tampering effectively.

The corrected program may include a function and a relative address list representing a relative address of each function in the corrected program.

The protection program may be subjected to reversible data conversion processing, and the non-protection program may contain an instruction for performing reverse conversion processing of the data conversion processing.

The addition of an error correction code and the reversible data conversion processing may be performed in any order. That is, the protection program may be obtained by performing the data conversion processing after adding an error correction code, or an error correction code may be added to the protection program after performing the data conversion processing.

The computer program may control a device including a restoration circuit for performing reverse conversion processing of the data conversion processing, and the instruction for performing the reverse conversion processing may allow the restoration circuit to perform the reverse conversion processing.

Thus, the reverse conversion processing is performed with respect to the protection program by a hardware circuit during execution of the protection program, whereby an operation of the program cannot be analyzed even by disassembling the program. This can prevent tampering more effectively.

A corrected program obtained as a result of the error correction and the reverse conversion processing of the protection program may include: a function; and a relative address list representing a relative address of each function in the corrected program.

Furthermore, in order to achieve the above-mentioned object, a device of the present disclosure includes a CPU, a program memory, and a rewritable memory, wherein the program memory stores a computer program for controlling the device via the CPU, the computer program includes a protection program with an error correction code added thereto, and a non-protection program containing an instruction for error-correcting the protection program and an instruction for invoking a corrected program that has been subjected to the error correction, the rewritable memory stores the corrected program obtained as a result of the error correction, and the CPU reads the corrected program from the rewritable memory for execution.

Thus, error correction is performed using a computer program with an error correction code added to a portion to be protected from tampering, and using the error correction code in execution of the protection program. Because of this, as long as tampering is in a correctable range even if the protection program is tampered with, the tampered protection program can be retuned to the state before tampering. This can provide a device capable of effectively preventing tampering of a program by a hacker and the like.

In a case where an error is detected from the protection program, at least a part of an operation of the device may be restricted when the error cannot be corrected.

According to the above-mentioned configuration, as long as tampering is in a correctable range even if the protection program is tampered with, the tampered program can be returned to the state before tampering by error correction. Therefore, there is no influence of tampering. Furthermore, if an error cannot be corrected, damages caused by tampering can be prevented by restricting at least a part of an operation of the device. Any suitable method may be used for restricting at least a part of an operation of the device, as long as damages caused by tampering can be prevented. Examples of the restriction method include, but are not limited to, suspension of an operation of a CPU or an entire device, termination of communication with a host or external device, and the like.

In a case where an error is detected from the protection program, at least a part of an operation of the device may be restricted irrespective of whether the error can be corrected.

According to the above configuration, in a case where the protection program is tampered with, if an error is detected, damages caused by tampering can be prevented more exactly by restricting at least a part of an operation of the device even when error correction is in a correctable range.

The above-mentioned computer program product further may include an error correction circuit, wherein the instruction for error-correcting the protection program may allow the error correction circuit to execute the error correction.

The CPU may delete the corrected program from the rewritable memory after executing the corrected program.

Because of this, the corrected program remaining in the rewritable memory can be prevented from being cracked by a hacker or the like. The corrected program only needs to be deleted to such a degree that the corrected program does not remain substantially in the rewritable memory. For example, the corrected program can be deleted by overwriting nonsignificant data.

The protection program further may be subjected to reversible data conversion processing, and the non-protection program may contain an instruction for performing reverse conversion processing of the data conversion processing.

The above-mentioned device further may include a restoration circuit for performing the reverse conversion processing of the data conversion processing, and the instruction for performing the reverse conversion processing of the data conversion processing may allow the restoration circuit to perform the reverse conversion processing.

The error correction circuit may be used as the restoration circuit.

When the error correction circuit is allowed to function as a restoration circuit, a device with a simplified configuration can be realized at low cost.

The corrected program obtained as a result of the error correction of the protection program may contain a function, and a relative address list representing a relative address of each function in the corrected program, and the relative address list may be placed at a predetermined position in the corrected program on the rewritable memory.

The corrected program obtained as a result of the error correction and the reverse conversion processing of the protection program may contain a function, and a relative address list representing a relative address of each function in the corrected program, and the relative address list may be placed at a predetermined position in the corrected program on the rewritable memory.

Furthermore, in order to achieve the above-mentioned object, a method for producing a computer program of the present disclosure for controlling an operation of a device having a CPU via the CPU, includes: creating a protection program with an error correction code added to a portion to be protected in the computer program; converting the protection program into a program source format, and combining the program source format with a program source of a non-protection program containing an instruction for performing error correction of the protection program and an instruction for invoking a corrected program; and compiling and linking the combined program source.

Because of this, a computer program with an error correction code added to a portion to be protected from tampering can be provided.

The computer program may control a device including an error correction circuit, and an instruction for performing error correction of the protection program may allow the error correction circuit to execute error correction.

The protection program further may include performing reversible data conversion processing, and the non-protection program may contain an instruction for performing reverse conversion processing of the data conversion processing.

The computer program may control a device including a restoration circuit for performing reverse conversion processing of the data conversion processing, and an instruction for performing the reverse conversion processing may allow the restoration circuit to perform reverse conversion processing.

The protection program may contain a function, and the above-mentioned method further may include creating a relative address list representing a relative address of each function in the protection program in the computer program.

Hereinafter, the present disclosure will be described by way of illustrative embodiments with reference to the drawings.

Embodiment 1

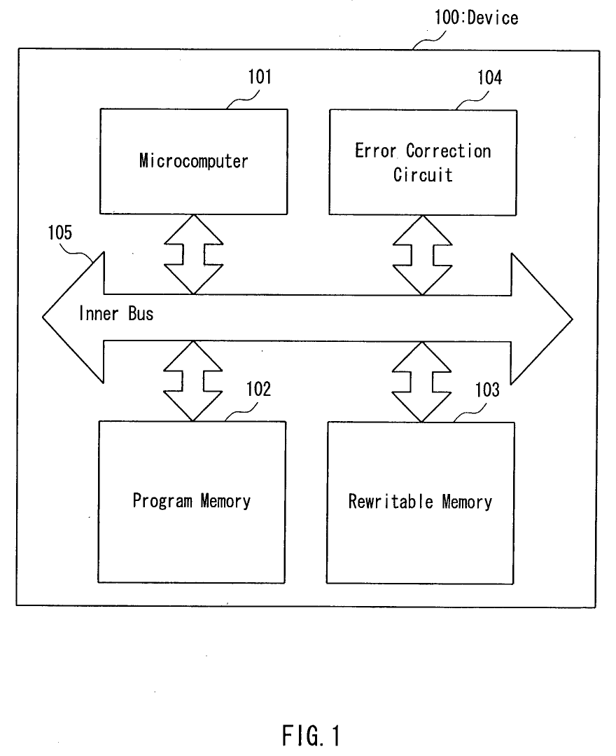

FIG. 1 is a block diagram showing an example of a configuration of a device 100 in Embodiment 1 according to the present disclosure. In FIG. 1, reference numeral 101 denotes a microcomputer that is a small operator, 102 denotes a program memory that is a non-volatile memory, 103 denotes a rewritable memory, 104 denotes an error correction circuit, and 105 denotes an internal bus.

The program memory 102 stores a control program. The microcomputer 101 controls the device 100 in accordance with instructions of the control program stored in the program memory 102. The rewritable memory 103 stores processing data of the microcomputer 101 temporarily. The error correction circuit 104 error-corrects data. The internal bus 105 connects the microcomputer 101, the program memory 102, the rewritable memory 103, and the error correction circuit 104 to each other. Herein, as the program memory 102, a read-only memory, a write-once memory, or a flash memory may be used. Furthermore, as the rewritable memory 103, a stack memory that does not require an operation of holding data or a dynamic memory that requires an operation of holding data (specifically, a DRAM), may be used.

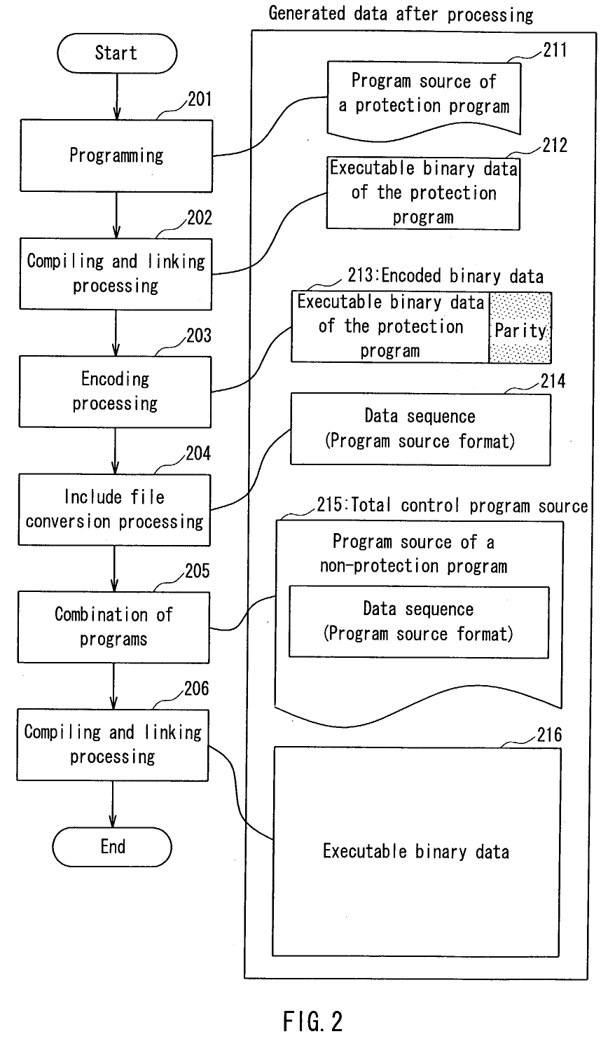

FIG. 2 is a flow chart showing a method for creating an executable control program, stored in the program memory 102. In the present specification, a protection program refers to a program to be protected from tampering. Redundant bits are added to the protection program. Furthermore, a program other than the protection program in the control program will be referred to as a non-protection program.

At Operation 201, a program source 211 of a portion corresponding to a protection program to be protected from tampering in the control program to be stored in the program memory 102 is generated.

At Operation 202, the program source 211 is complied and linked to generate executable binary data 212.

At Operation 203, redundant bits (parity code) are added to the executable binary data 212, and the resultant binary data 212 is encoded to an error correction code, whereby binary data 213 is generated. An encoding method will be described later. At this time, the binary data 213 is increased in size at least by the parity code, compared with the binary data 212 before being encoded. Because of this encoding processing, an error is detected and corrected by the error correction circuit 104 of the device 100. Thus, in the case where a program is tampered with, the tampered program can be detected and returned to an original program.

At Operation 204, the binary data 213 is converted to a data sequence 214 in a program source format so as to be incorporated into another program source easily. As the program source format of the data sequence 214, for example, an include file format having a character-type array expression of the C language as contents can be used.

At Operation 205, the protection program converted to the data sequence 214 is inserted in a program source of a non-protection program to create a total control program source 215. The non-protection program contains a program for invoking the protection program.

At Operation 206, the total control program source 215 is compiled and linked to generate executable binary data 216 to be stored in the program memory 102. Because of this, a control program with a parity code added to a protection program is formed as the binary data 216.

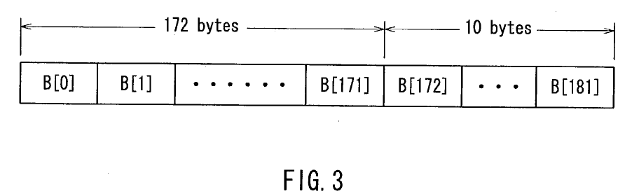

Next, as an example of a method for encoding the executable binary data 212, a method will be described for encoding the data into a Reed-Solomon (RS) code with a code length of 182 bytes, the number of information of 172 bytes, and a parity code of 10 bytes, which is an inner code (PI) of a DVD shown in FIG. 3.

FIG. 3 is a diagram showing a configuration of the PI. B[i] (i=0 to 181) represents 1 byte that corresponds to 8 bits. B[0] to B[171] represent a data portion, and B[172] to B[181] represent a parity portion. Each 8 bit of the executable binary data 212 corresponds to B[0] to B[171]. In the case where original binary data does not have 172 bytes, data padded with 0 is added to the original binary data. The parity portion of the PI is represented polynomially by the following parity check code polynomial P(X):

P(X)=I(X)X¹⁰mod G(X) (1)

where I(X) is called an information symbol polynomial that represents a data portion polynomially:

$$I ( X ) = {\sum }_{i = 0}^{171} B [ i ] \cdot {X}^{171 - i} \qquad ( 2 )$$

G(X) is represented by the following generator polynomial:

$$G ( X ) = {\prod }_{k = 0}^{9} ( X + {α}^{k} ) \qquad ( 3 )$$

where α is a root of the following primitive polynomial:

x⁸+x⁴+x³+x²+1=0 (4)

The parity portion of the PI also can be represented polynomially as follows:

$$P ( X ) = {\sum }_{i = 172}^{181} B [ i ] \cdot {X}^{181 - i} \qquad ( 5 )$$

That is, by comparing the coefficient of X in Expression 1 with that in Expression 5, the value of the parity portion B[172] to B[181] is determined. Any suitable method may be used for solving Expressions 1 to 5.

The above-mentioned encoding processing is realized by software or the like and is performed until all the executable binary data 212 is encoded, whereby the binary data 213 with a parity code added thereto is generated.

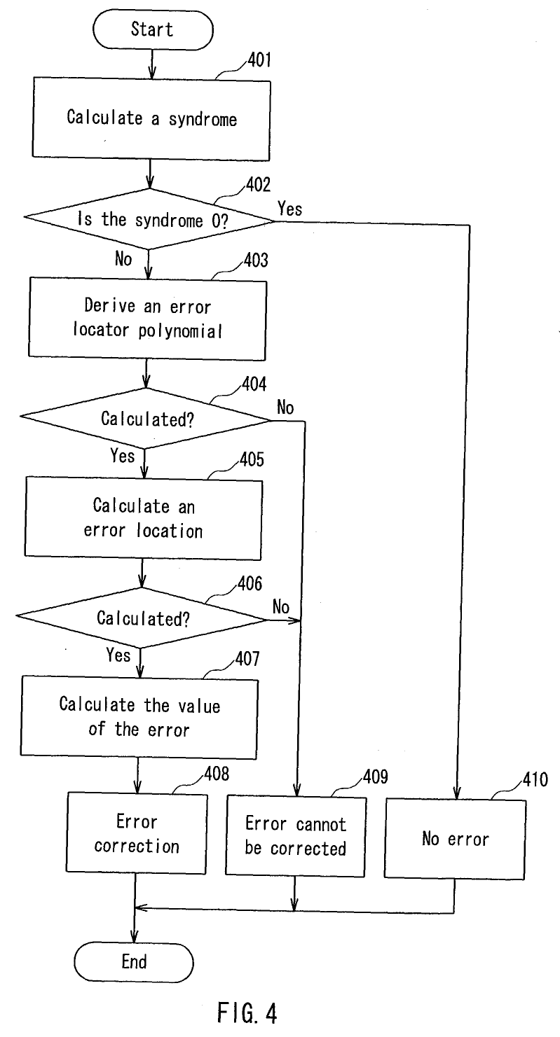

Hereinafter, an example of a method for error-correcting a protection program in a control program in the case of attempting to execute the control program of the present disclosure by a microcomputer will be described with reference to FIG. 4. FIG. 4 is a flow chart illustrating an example of a method for error-correcting a protection program. Herein, the case where the protection program is encoded to the above-mentioned PI will be exemplified. First, at Operation 401, a syndrome representing positional information for specifying an error portion is calculated. Assuming that data to be error-corrected is represented by the following expression:

R=(B[0] B[1] . . . B[180] B[181]) (6)

the syndrome can be defined as follows:

sᵢ=R(αⁱ)=B[0]α¹⁸¹ⁱ+B[1]α¹⁸⁰ⁱ+ . . . +B[180]αⁱ+B[181] (7)

At Operation 402, if the syndrome is 0, it is determined that there is no error. The process proceeds to Operation 410, and the microcomputer is notified of the absence of an error. Thus, the error correction processing is completed. If the syndrome is not 0, the process proceeds to the subsequent Operation.

At Operation 403, an error locator polynomial is derived from the syndrome. The error locator polynomial has reciprocals of error locations L₁, L₂, . . . , Lₘ (“m” is the number of errors) as a root, which is represented by the following expression:

$$\begin{matrix}σ ( x ) = ( 1 - {σ}^{{L}_{1}} x ) ( 1 - {σ}^{{L}_{2}} x ) ⋯ ( 1 - {σ}^{{L}_{m}} x ) \\ = {σ}_{m} {X}^{m} + {σ}_{m - 1} {x}^{m - 1} + ⋯ + {σ}_{1} x + 1\end{matrix} \qquad ( 8 )$$

The coefficient of the error locator polynomial is defined by the syndrome and is obtained by an algorism such as a Peterson method for solving simultaneous equations, held between the coefficient of the error locator polynomial and the syndrome, using a matrix; or sequential calculating method (e.g., an Euclid's algorithm and a BM method) for solving the simultaneous equations, using a polynomial.

At Operation 404, when the error locator polynomial has been calculated, the process proceeds to the subsequent operation. When the error locator polynomial has not been calculated, it is determined that there are more errors than the correctable number. The process proceeds to Operation 409, and the microcomputer is notified that the errors cannot be corrected. Thus, the error correction processing is completed.

At Operation 405, α⁻ⁱ(i=0 to 181) that is the root of the primitive polynomial (Expression 4) is substituted successively into the error locator polynomial, and “i” that allows the error locator polynomial to be 0 is obtained, whereby the error location is calculated.

At Operation 406, when the error location has been calculated, the process proceeds to the subsequent operation. If the error location has not been calculated, the process proceeds to Operation 409, and the microcomputer is notified that the errors cannot be corrected. Thus, the error correction processing is completed.

At Operation 407, the value of the error is calculated by solving the simultaneous expressions between the error location obtained at Operation 406 and the syndrome.

At Operation 408, the value of the error obtained at Operation 407 is subtracted from the value of data corresponding to the error location obtained at Operation 406, whereby data to be error-corrected is corrected.

The error correction circuit 104 in FIG. 1 can have any configuration, as long as it can perform the processing of the above-mentioned error correction procedure. Furthermore, the above-mentioned PI code and encoding method thereof are described merely for illustrative purposes. Any code and any encoding method may be used as long as the code can be error-corrected. Furthermore, regarding the method for error correction, any suitable method may be used as long as it can detect and correct an error.

For example, in the above description, the case where the Reed-Solomon (RS) code is used as an error correction code has been described. However, the error correction code is not limited to the RS code. Besides this, for example, any code such as an error correction code used for a so-called Blu-ray Disk, a BCH code, and a convolutional code can be used.

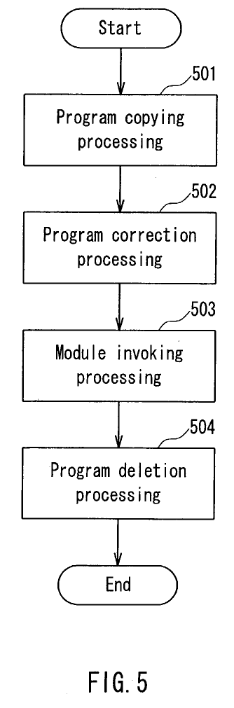

Hereinafter, the control program of the present disclosure will be described by way of an example of a procedure in the case where the control program of the present disclosure is executed by the device 100 of the present disclosure with the configuration shown in FIG. 1, with reference to FIGS. 5 to 8.

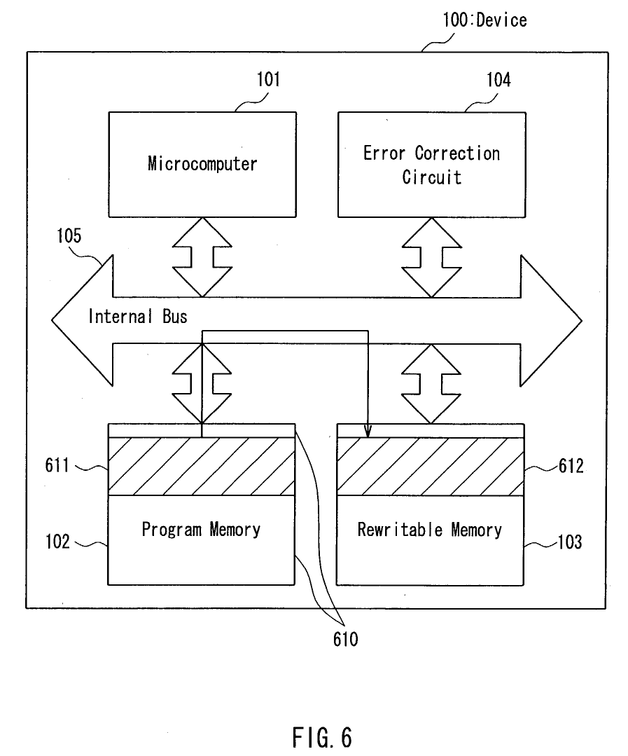

FIG. 5 is a flow chart illustrating a method for executing an instruction of a protection program. FIGS. 6, 7, and 8 show the states of the device at Operations 501, 502, and 503 in FIG. 5.

In FIGS. 6, 7, and 8, the same components as those in FIG. 1 are denoted with the same reference numerals as those therein, and the description thereof will be omitted here.

In the present specification, a program obtained by performing error correction processing with respect to a protection program will be referred to as a corrected program.

First, at Operation 501, a protection program 611 in the control program stored in the program memory 102 is copied to the rewritable memory 103 in accordance with an instruction from the microcomputer 101, whereby a copied program 612 is created, as shown in FIG. 6. The contents of the copied program 612 are the same as those of the protection program 611. In the program memory 102 in FIG. 6, a non-protection program 610 is stored in a region other than the region where the protection program 611 is stored. The non-protection program 610 contains an instruction for invoking a function in the protection program 611 (described later in detail).

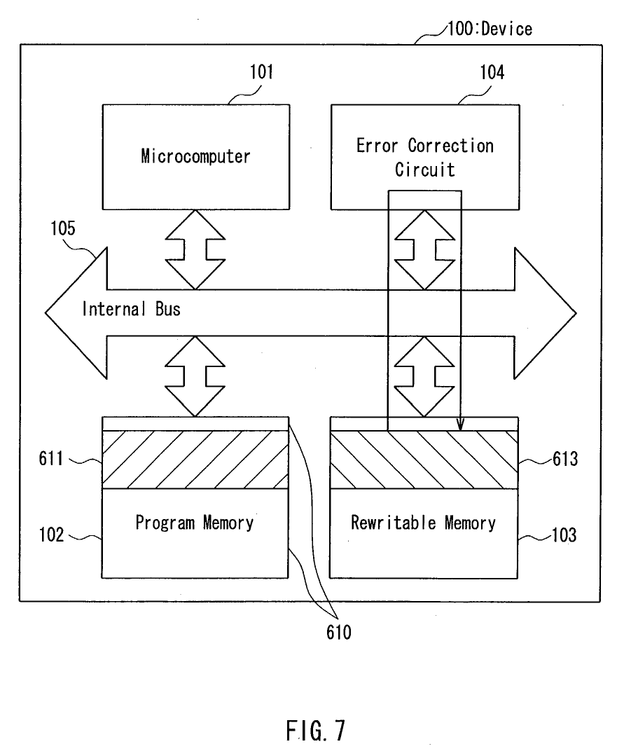

At Operation 502, the copied program 612 on the rewritable memory 103 is error-corrected by using the error correction circuit 104 in accordance with an instruction from the microcomputer 101, whereby a corrected program 613 is generated on the rewritable memory 103, as shown in FIG. 7. The error correction may be performed, for example, in accordance with the procedure described above with reference to FIG. 4.

In the case where the error correction circuit 104 detects an error, and the microcomputer 101 is notified that the error cannot be corrected (Operation 409 in FIG. 4), the microcomputer 101 determines that the control program has been tampered with. Then, the microcomputer 101 performs processing such as disconnection of communication with a host apparatus (not shown), and thereafter, suspends the operation of the microcomputer 101 or the entire device 100. In the case where the error detected by the error correction circuit 104 can be corrected, the microcomputer 101 corrects the error (Operation 408 in FIG. 4), thereby returning the tampered control program to the original control program. In the case where the error is detected, even if the error can be corrected, processing, such as disconnection of communication with a host apparatus and suspension of the operation of the microcomputer 101 or the entire device 100, may be performed. By performing such processing, it is possible to prevent a program (i.e., a tampered program) other than the authorized control program from being operated in the device 100.

For example, it is assumed that the above scheme is applied to the control program for performing processing of preventing unauthorized copying of a DVD that stores contents to be copyrighted. That is, it is assumed that the device 100 is a DVD recorder, and in the control program for controlling recording to a DVD in the device 100, an unauthorized copying prevention program as a protection program is provided with, for example, an error correction code, as described with reference to FIG. 2. For example, even if the protection program has been tampered with for the purpose of unauthorized copying to a DVD, as long as the tampering is in a range correctable by an error correction code, the protection program can be returned to the original program by error correction. In the case where the tampering cannot be corrected, the operation of the microcomputer 101 or the entire device 100 is suspended, whereby unauthorized copying is prevented. Thus, no matter how tampering occurs, unauthorized copying is prevented so as to protect the copyright of the contents of a DVD. Furthermore, as long as the tampering is in a correctable range, the tampered portion is corrected and returned to the original program. Therefore, the program that might have been tampered with is operated in the same way as in the program before being tampered with. This can confuse a person who has tampered with the program, and make it difficult to crack or tamper with the control program.

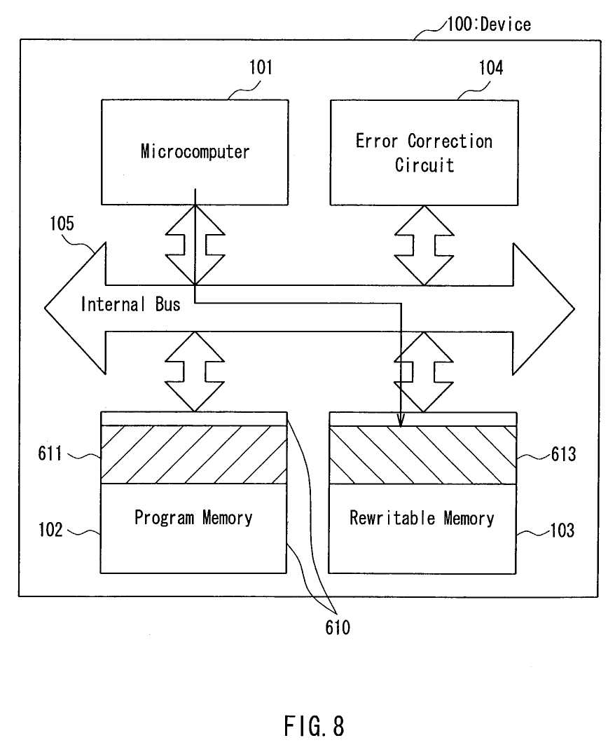

At Operation 503, the microcomputer 101 invokes a function (also called a module) in the corrected program 613 shown in FIG. 8. The module invoking processing will be described later in detail.

At Operation 504, after returning from the invoked function, the microcomputer 101 overwrites a value (e.g., 0) that is nonsignificant to the entire region where the corrected program 613 is present, shown in FIG. 8, whereby the corrected program 613 is deleted.

Although all the error correction processing at Operation 502 can be executed by software, if a software portion for performing the error correction processing is analyzed, there is a possibility that the protection program is cracked. Therefore, as in Embodiment 1 of the present disclosure, it is preferable that error correction processing is performed by using the error correction circuit 104 that is hardware peculiar to the device 100. Because of this, only a user of the device 100 can use the control program, so that the protection program can be prevented from being cracked.

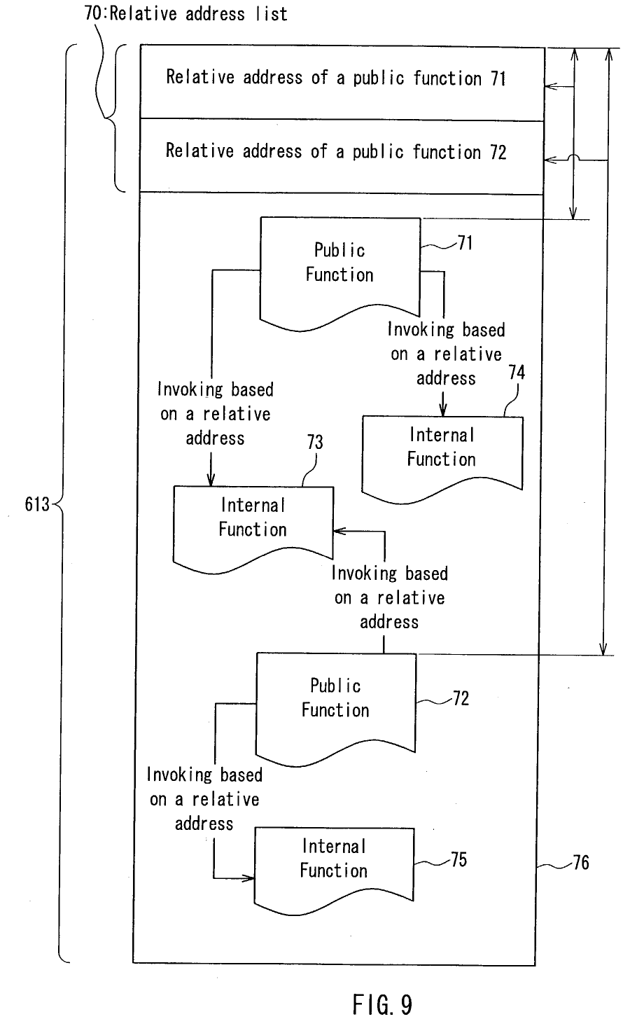

Next, a specific example of function invoking processing (Operation 503 in FIG. 5) will be described. FIG. 9 conceptionally shows the configuration of the corrected program 613 obtained by error-correcting the protection program 611 in FIG. 6 by the error correction circuit 104. The corrected program 613 includes a relative address list 70 and a program portion 76. The program portion 76 includes public functions 71 and 72 to be invoked from outside (i.e., the non-protection program 610 in FIG. 6) of the corrected program 613, and internal functions 73, 74, and 75 to be invoked from inside of the corrected program 613 based on a relative address. For example, the public functions 71 and 72 are invoked from the non-protection program 610. The public function 71 invokes the internal functions 73 and 74 based on relative addresses. The public function 72 invokes the internal functions 73 and 75 based on relative addresses. An arbitrary number of functions can be invoked by a public function.

The relative address list 70 lists relative addresses of the public functions 71 and 72 seen from the leading edge of the corrected program 613. The information on these addresses does not depend upon the position of the corrected program 613 with respect to the rewritable memory 103 in FIG. 8. Such information can be realized by programming so as to create the table at Operation 201 in FIG. 2.

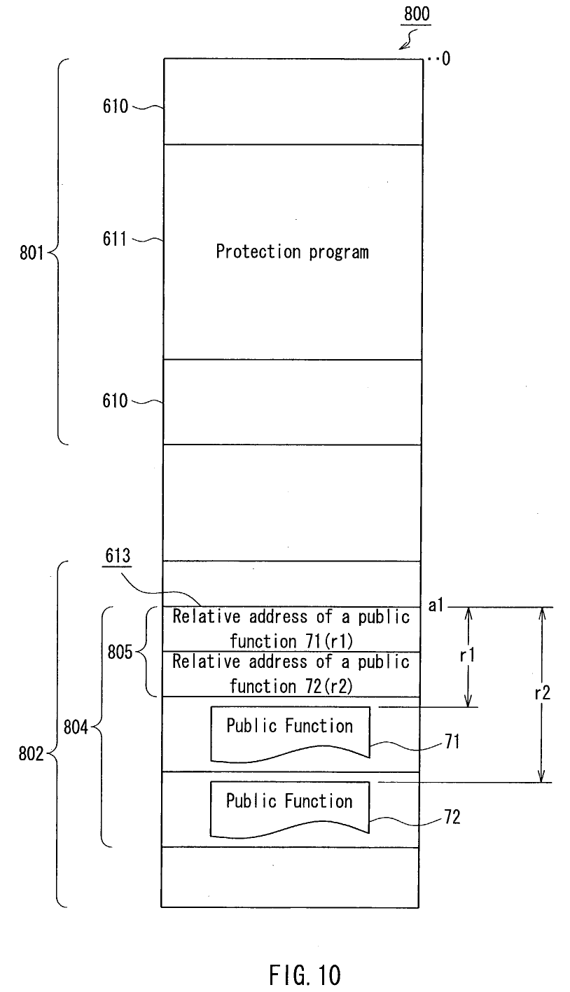

FIG. 10 shows an address space 800 with respect to the microcomputer 101. In the address space 800 with respect to the microcomputer 101, the program memory 102 and the rewritable memory 103 are placed in regions 801 and 802 assigned individual addresses. The corrected program 613 is obtained, as described above, by copying the protection program 611 and correcting it by the error correction circuit 104. The corrected program 613 is placed in a region (region 804 in FIG. 10) having a predetermined address (address “a1” in FIG. 10) specified by the microcomputer 101 at the leading edge thereof in the region 802 assigned to the rewritable memory 103. At this time, the relative address list 70 is disposed at the leading edge of the corrected program 804 (region 805 in FIG. 10). The relative address list 70 includes a relative address “r1” of the public function 71 and a relative address “r2” of the public function 72.

The absolute address of the public function 71 in the address space 800 is obtained by adding the relative address “r1” of the public function 71 to the leading edge address “a1” of the corrected program 613. Therefore, the microcomputer 101 can invoke the public function 71 by specifying the absolute address of the public function 71 in the address space 800. Similarly, the public function 72 can be invoked by specifying the absolute address obtained by adding a relative address “r2” of the public function 72 to the leading edge address “a1” of the corrected program 613.

The relative address list 805 of the corrected program 613 shown in FIG. 10 is disposed at the leading edge of the corrected program 805. The relative address list 805 only needs to be disposed at a position where it can be specified from an external program i.e., the non-protection program 610) with respect to the corrected program 613.

Embodiment 2

Another embodiment of the present disclosure will be described below.

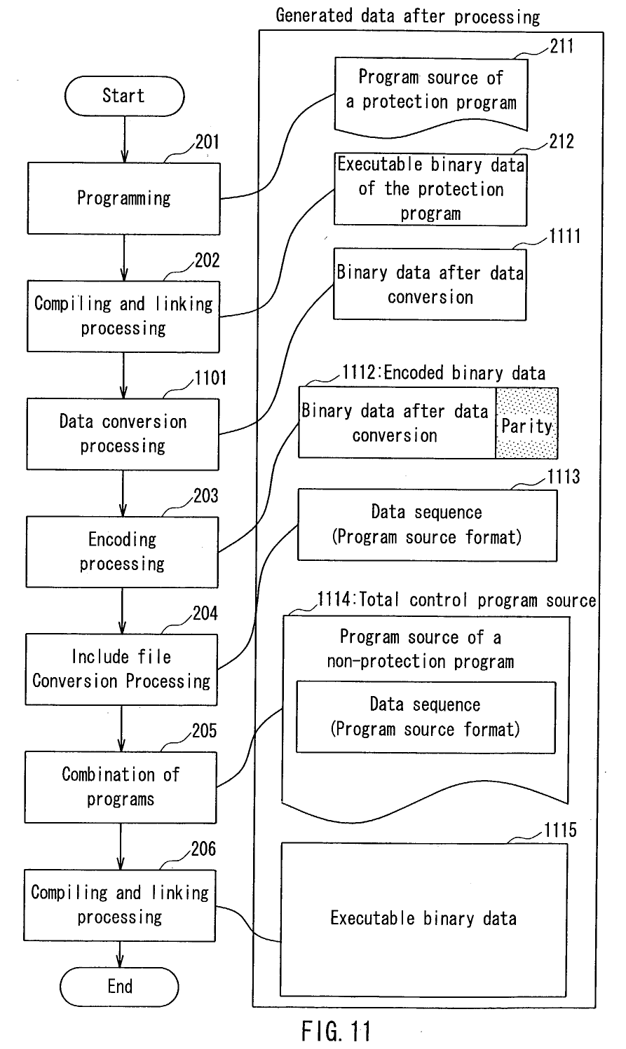

FIG. 11 is a flow chart showing a method for creating an executable control program of Embodiment 2 according to the present disclosure. In FIG. 11, the same processing and data as those in FIG. 2 are denoted with the same reference numerals as those therein, and the description thereof will be omitted here. Embodiment 2 is different from Embodiment 1 in that data conversion processing (Operation 1101) for subjecting a protection program portion in a control program to reversible data conversion is added between Operations 202 and 203.

At Operation 1101, the executable binary data 212 generated at Operation 202 is subjected to a reversible data conversion, whereby converted binary data 1111 is generated. The data conversion processing (Operation 1101) will be described in detail later. Even if the binary data 1111 is subjected to processing by a microcomputer directly, the microcomputer is not allowed to perform a desired operation. Furthermore, only data conversion is performed, so that a program size is not changed before and after Operation 1101. Because of this data conversion processing, a protection program according to this embodiment becomes unlikely to be analyzed and tampered with by software processing such as disassembling.

At Operation 203, the binary data 1111 is encoded, whereby encoded binary data 1112 is obtained. Then, at Operation 204, the binary data 1112 is converted to a data sequence 1113 in a program source format. At Operation 205, the data sequence 1113 is combined with a program source of a non-protection program, whereby a total control program source 1114 is obtained. Finally, the total control program source 1114 is complied and linked to generate executable binary data 1115. The executable binary data 1115 is stored in the program memory.

Compared with Embodiment 1, the binary data 1111 is encoded at Operation 203 after being subjected to data conversion at Operation 1101, so that the binary data 1112, the data sequence 1113, the total control program source 1114, and the binary data 1115 are different from the binary data 213, the data sequence 214, the total control program source 215, and the binary data 216, respectively. However, the respective size is the same.

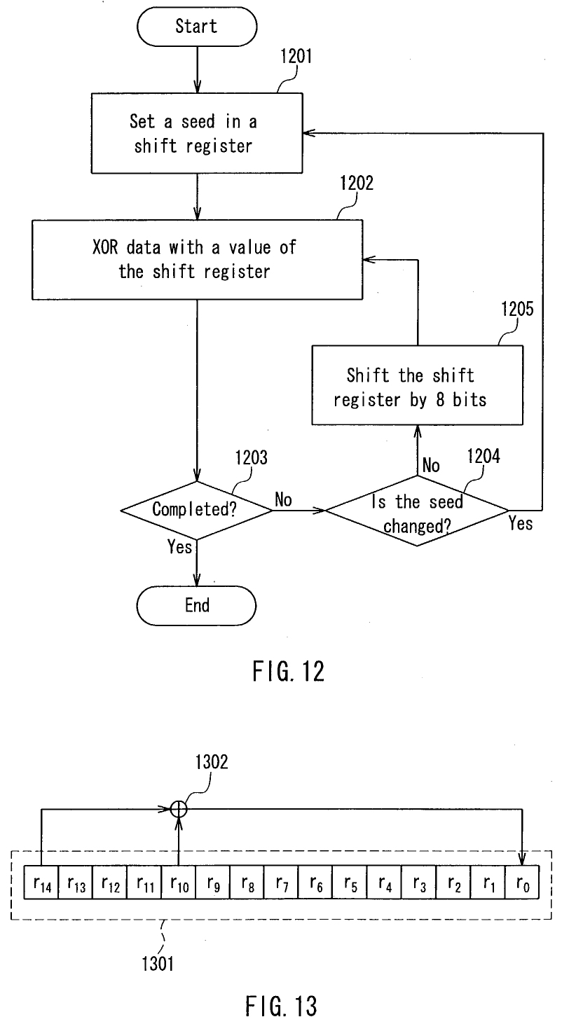

Next, an example of the data conversion processing (1101 in FIG. 11) of the executable binary data 212 will be described with reference to FIG. 12. FIG. 12 is a flow chart illustrating an example of a method for converting binary data. FIG. 13 shows an example of a circuit for performing data conversion processing at Operation 1101, which is the same circuit as a scramble circuit used for scrambling data in a DVD. In FIG. 13, “r₀” to “r₁₄” represent values of a 1-bit shift register, 1301 denotes a shift register, and 1302 denotes a 1-bit XOR. Herein, a method for converting the binary data 212 by 8 bits with the shift register 1301 in FIG. 13 will be exemplified.

First, at Operation 1201, a 15-bit seed, which is an initial value of scramble, is set in the shift register 1301. At Operation 1202, assuming that 8 bits of the binary data 212 to be converted are “d₀” (lowest-order bit) to “d₇” (highest-order bit), 8 bits of “r₀” to “r₇” of the shift register 1301 are XORed with 8 bits of “d₀” to “d₇” to convert data. At Operation 1203, if all the binary data 212 has been converted, the data conversion processing is completed. Otherwise, the process proceeds to Operation 1204. At Operation 1204, if the seed is changed, the process proceeds to Operation 1201. Otherwise, the process proceeds to Operation 1205. The seed is changed every time the binary data 212 is converted by the predetermined number of bytes. At Operation 1205, the shift register 1301 is shifted by 8 bits, and the process proceeds to Operation 1202. The above processing is continued until all the binary data 212 is converted, whereby converted binary data (1111 in FIG. 11) is generated.

For example, when “r₀” is set to be 1 and “r₁” to “r₁₄” are set to be 0 as the seed, and binary data represented in a hexadecimal notation (i.e., 00, 01, 02, 03) is converted in the above-mentioned procedure, 00 is XORed with 01 to be converted to 01. 01 is XORed with 00 after the seed is shifted by 8 bits to be converted to 01. 02 and 03 are XORed with 22 and 04, respectively, to be converted to 20 and 07.

The above-mentioned method for data conversion by scramble used in a DVD is merely an example. Any suitable method may be used as long as it can perform reversible data conversion.

For example, data conversion may be performed by using a shift register used in a Blu-ray Disc drive. Furthermore, a power representation “αⁱ” (i=0 to 254) of an element of a Galois extension field GF (2⁸), which is generated by adding “α” (i.e., root of the primitive polynomial (Expression 4)) to a ground field GF (2) used in an error correction theory, can be represented by a polynomial as a remainder obtained by dividing αⁱ by Expression 4, as represented by the following Expression 9:

$$\begin{matrix}{α}^{i} = {α}^{i} mod ( {α}^{8} + {α}^{4} + {α}^{3} + {α}^{2} + 1 ) \\ = {\sum }_{j = 0}^{7} {v}_{j} \cdot {α}^{j}\end{matrix} \qquad ( 9 )$$

Herein, “vj” represents a coefficient of the polynomial. The coefficient of the polynomial represented by a vector is a vector representation, which is represented by an 8-dimensional vector. Therefore, the power representation of an element corresponds to the vector representation in a one-to-one relationship, and a multiplier “i” in the power representation also corresponds to a 8-bit value obtained by considering each element of the vector representation as one bit. If the 8-bit value at i=255 is assumed to be 0, the following Expression 10 is obtained, whereby reversible 8-bit data conversion can be performed. Thus, the binary data 212 may be converted by 8 bits, using the above correspondence relationship.

$$\{ \begin{matrix}f ( i ) = {\sum }_{j = 0}^{7} {v}_{j} \cdot {2}^{j} ( i = 0 … 254 ) \\ f ( 255 ) = 0\end{matrix} \qquad ( 10 )$$

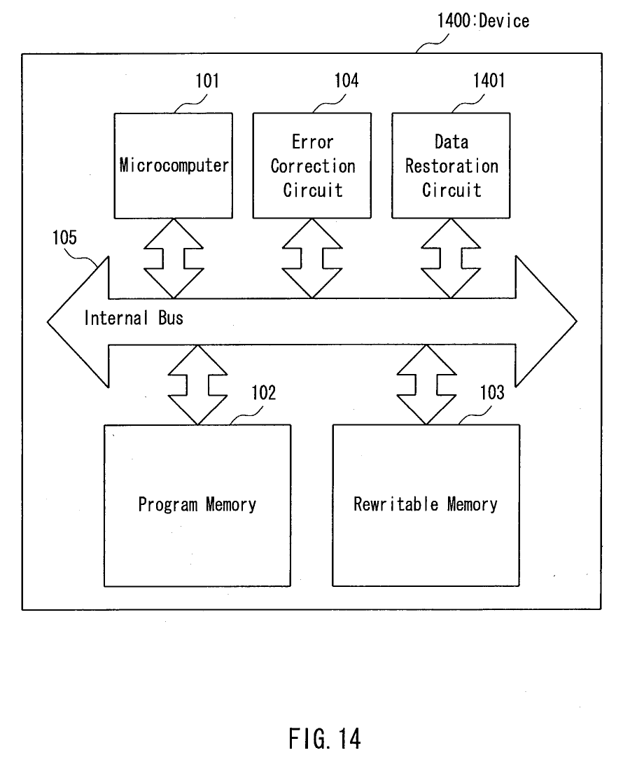

FIG. 14 is a block diagram showing an example of a configuration of a device 1400 in Embodiment 2 according to the present disclosure. In FIG. 14, the same components as those in FIG. 1 are denoted with the same reference numerals as those therein, and the description thereof will be omitted here. The device 1400 is different from the device 100 in Embodiment 1, mainly in that a data restoration circuit 1401 for subjecting a reversibly converted protection program to reverse conversion is added.

In restoring converted data by the data conversion processing in FIG. 12, the data restoration circuit 1401 restores binary data to be restored by the same processing as that in FIG. 12, instead of the binary data 212 to be converted. Therefore, as the data restoration circuit 1401, any circuit capable of performing the processing at Operations 1202 to 1205 in FIG. 12 may be used. In the case where the device 1400 is a DVD drive or a Blu-ray Disk drive, if these drives use a scramble circuit that is conventionally included therein as the data restoration circuit 1401, the following advantages are obtained: (1) it is not required to design a new circuit; and (2) data can be made more difficult to crack when a seed is changed by software. Furthermore, when data conversion is performed by using the correspondence relationship between the multiplier “i” in the power representation of an element of the Galois extension field GF (2⁸) and the 8-bit value obtained by considering each element of the vector representation as one bit, since a data restoration circuit for restoring the converted data based on the above correspondence relationship generally is present in an error correction circuit, the error correction circuit 104 also can be used as the data restoration circuit 1401, instead of separately providing the data restoration circuit as shown in FIG. 14. Furthermore, an encryption circuit also can be used as the data restoration circuit (it also is possible that encryption processing is performed as data conversion processing, and a decryption circuit is used as the data restoration circuit).

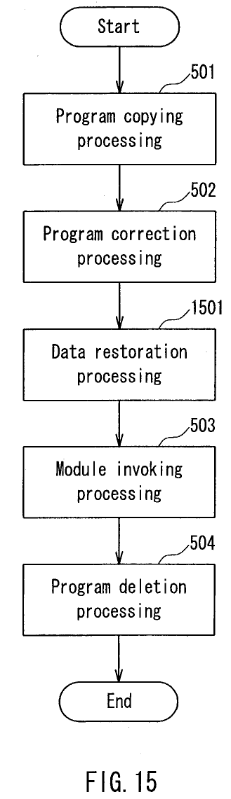

FIG. 15 is a flow chart illustrating a method for executing an instruction of a control program in Embodiment 2 according to the present disclosure. In FIG. 15, the same processing as that in FIG. 5 is denoted with the same reference numeral as that therein, and the description thereof will be omitted here. Embodiment 2 is different from Embodiment 1 in that data restoration processing (Operation 1501) is added. In FIG. 15, the data restoration processing (Operation 1501) is performed after program correction processing (Operation 502). However, Operations 502 and 1501 may be performed in any order, as long as the order is opposite to Operations 1101 and 203 of the method for creating an executable control program in FIG. 11.

Although all the data restoration processing at Operation 1501 can be executed by software, there is a possibility the data is cracked by disassembling or the like. Therefore, as in Embodiment 2 of the present disclosure, it is preferable that data restoration processing is performed by using the data restoration circuit 1401 that is hardware peculiar to the device 1400. Because of this, only a user of the device 1400 can use a control program, and the protection program can be prevented from being cracked.

The other operations are the same as those in Embodiment 1. Thus, according to the present embodiment, because of the data conversion processing, a protection program becomes unlikely to be tampered with. Furthermore, even if the protection program is tampered with, by detecting and correcting the tampering with an error correction code, an operation without authorization can be stopped.

A method for invoking a function in a protection program in the present embodiment is the same as that in Embodiment 1.

As described above, according to the present disclosure, a program to be protected from tampering is encoded, a control program including the protection program is created, and the control program is error-corrected by an error correction circuit. Thus, the tampering can be detected and corrected, so that the operation other than the designed control program cannot be performed. Furthermore, by adding data conversion processing at a time of creating a control program and adding data restoration processing performed by a data restoration circuit at a time of executing a control program, the control program becomes more unlikely to be tampered with. Furthermore, if a correction algorithm and a restoration algorithm of the control program are allowed to be shared between the hardware incorporated in a device and the control program, even a person having a very high software technique does not understand the control program merely by analyzing it. Furthermore, compared with the case where all the processing to be protected is realized by hardware or the case where all the processing to be protected is realized by software, the present embodiment is excellent in terms of a developing period, cost, and safety.

The following are preferable application examples of the present disclosure, which will be shown merely for illustrative purpose and do not limit the present disclosure.

1. Application to a program for region code comparison processing:

A DVD and a DVD reproducing apparatus are provided with a region code for identifying a region. In the case of reproducing data from a DVD, a region code added to a disk is compared with a region code added to a reproducing apparatus, and only in the case where a reproducible region is confirmed, the data is reproduced from the DVD. The reason for performing region code comparison processing is as follows.

For example, it is assumed that a DVD for a movie is on sale in one country, and the movie still is on view in a movie theater in another country. If the DVD put on the market in the former country can be seen by a reproducing apparatus in the latter country, the number of people who try to see the movie in movie theaters decreases. In this case, the DVD is set so that data is not reproduced therefrom in regions where the movie still is on view or before screening, by performing region code comparison processing, whereby the above-mentioned problem can be prevented.

Furthermore, in the case where there is a region where particular contents are prohibited from being reproduced for religious reasons and the like, the prohibited contents can be set so as not to be reproduced by performing region code comparison processing.

However, in the case where the control program of region code comparison processing is tampered with so as to prevent comparison processing, data is reproduced from a DVD even in a region where the data is not permitted to be reproduced from the DVD. Thus, the above-mentioned regional protection cannot be performed.

By using the control program for region code comparison processing as a protection program and adding an error correction code thereto, as long as tampering is in a correctable range even if the control program is tampered with, reproduction without authorization can be prevented by performing correct region code comparison processing. Furthermore, even in the case where correction cannot be performed, tampering can be found. Therefore, reproduction can be prevented by suspending equipment and the like. Thus, reproduction without authorization can be prevented no matter how the control program is tampered with.

2. Application to a program for mutual authentication processing between a drive and a host:

When data of a DVD is reproduced or copied, mutual authentication is performed between a DVD drive and a host. Only in the case where mutual authentication can be confirmed, a key for decrypting encrypted data is given to a host. However, in the case where the program for mutual authentication processing is tampered with so that mutual authentication is not performed, a key for decrypting encrypted data is given to a host unconditionally. Therefore, a copyright cannot be protected.

When a program for mutual authentication processing is used as a protection program and is provided with an error correction code, as long as tampering is in a correctable range even if the program is tampered with, the program can be corrected to the state before tampering. Because of this, correct mutual authentication processing can be performed. Furthermore, even if correction cannot be performed, tampering is found. Therefore, a key for decrypting a code can be prevented from being given to a host. Thus, no matter how the program is tampered with, reproduction and copying without authorization can be prevented.

The present disclosure can be carried out as a computer-usable or computer-readable computer program product. The computer program product of the present disclosure may use any media for embodying the above-mentioned control program. The media include a carrier medium for introducing a control program to a device by radio communication or cable communication, in addition to any recording media capable of storing a control program. Examples of the recording media are not so limited. Examples of the recording media include a magnetic tape, a magnetic disk, an optical disk, a magnetooptical disk, a magnetic card, a memory, and the like. Furthermore, a control program may be, for example, in a compressed state on a recording medium or a carrier medium.

The invention may be embodied in other forms without departing from the spirit or essential characteristics thereof. The embodiments disclosed in this application are to be considered in all respects as illustrative and not limiting. The scope of the invention is indicated by the appended claims rather than by the foregoing description, and all changes that come within the meaning and range of equivalency of the claims are intended to be embraced therein.

What is claimed is:

1. A computer program product comprising a medium for embodying a computer program for controlling an operation of a device having a CPU via the CPU, the computer program comprising:
a protection program with an error correction code added thereto; and
a non-protection program containing an instruction for error-correcting the protection program and an instruction for invoking a corrected program that has been subjected to the error correction.

2. A computer program product according to claim 1, wherein the computer program controls a device including an error correction circuit, and
the instruction for error-correcting the protection program allows the error correction circuit to perform the error correction.

3. A computer program product according to claim 1, wherein the corrected program comprises:
a function; and
a relative address list representing a relative address of each function in the corrected program.

4. A computer program product according to claim 1, wherein the protection program further is subjected to reversible data conversion processing, and
the non-protection program contains an instruction for performing reverse conversion processing of the data conversion processing.

5. A computer program product according to claim 4, wherein the computer program controls a device including a restoration circuit for performing reverse conversion processing of the data conversion processing, and
the instruction for performing the reverse conversion processing allows the restoration circuit to perform the reverse conversion processing.

6. A computer program product according to claim 4, wherein a corrected program obtained as a result of the error correction and the reverse conversion processing of the protection program comprises:
a function; and
a relative address list representing a relative address of each function in the corrected program.

7. A device comprising a CPU, a program memory, and a rewritable memory,
wherein the program memory stores a computer program for controlling the device via the CPU,
the computer program includes a protection program with an error correction code added thereto, and a non-protection program containing an instruction for error-correcting the protection program and an instruction for invoking a corrected program that has been subjected to the error correction,
the rewritable memory stores the corrected program obtained as a result of the error correction, and
the CPU reads the corrected program from the rewritable memory for execution.

8. A device according to claim 7, wherein, in a case where an error is detected from the protection program, at least a part of an operation of the device is restricted when the error cannot be corrected.

9. A device according to claim 7, wherein, in a case where an error is detected from the protection program, at least a part of an operation of the device is restricted irrespective of whether the error can be corrected.

10. A device according to claim 7, further comprising an error correction circuit,
wherein the instruction for error-correcting the protection program allows the error correction circuit to execute the error correction.

11. A device according to claim 7, wherein the CPU deletes the corrected program from the rewritable memory after executing the corrected program.

12. A device according to claim 7, wherein the protection program further is subjected to reversible data conversion processing, and
the non-protection program contains an instruction for performing reverse conversion processing of the data conversion processing.

13. A device according to claim 12, further comprising a restoration circuit for performing the reverse conversion processing of the data conversion processing, and
the instruction for performing the reverse conversion processing of the data conversion processing allows the restoration circuit to perform the reverse conversion processing.

14. A device according to claim 13, wherein the error correction circuit is used as the restoration circuit.

15. A device according to claim 7, wherein the corrected program obtained as a result of the error correction of the protection program contains a function, and a relative address list representing a relative address of each function in the corrected program, and
the relative address list is placed at a predetermined position in the corrected program on the rewritable memory.

16. A device according to claim 12, wherein the corrected program obtained as a result of the error correction and the reverse conversion processing of the protection program contains a function, and a relative address list representing a relative address of each function in the corrected program, and
the relative address list is placed at a predetermined position in the corrected program on the rewritable memory.

17. A method for producing a computer program for controlling an operation of a device having a CPU via the CPU, comprising:
creating a protection program with an error correction code added to a portion to be protected in the computer program;
converting the protection program into a program source format, and combining the program source format with a program source of a non-protection program containing an instruction for performing error correction of the protection program and an instruction for invoking a corrected program; and
compiling and linking the combined program source.

18. A method for producing a computer program according to claim 17, wherein the computer program controls a device including an error correction circuit, and
an instruction for performing error correction of the protection program allows the error correction circuit to execute error correction.

19. A method for producing a computer program according to claim 17, wherein the protection program further comprises performing reversible data conversion processing, and
the non-protection program contains an instruction for performing reverse conversion processing of the data conversion processing.

20. A method for producing a computer program according to claim 17, wherein the computer program controls a device including a restoration circuit for performing reverse conversion processing of the data conversion processing, and
an instruction for performing the reverse conversion processing allows the restoration circuit to perform reverse conversion processing.

21. A method for producing a computer program according to claim 17, wherein the protection program contains a function, and
the method further comprising creating a relative address list representing a relative address of each function in the protection program in the computer program.
